(19) United States
(12) Patent Application Publication
(10) Pub. No.: US 2023/0209812 A1
(43) Pub. Date: Jun. 29, 2023

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventors: Zhong KONG, Hefei (CN); Hai-Han Hung, Hefei (CN)

(21) Appl. No.: 18/177,807

(22) Filed: Mar. 3, 2023

Related U.S. Application Data
(63) Continuation of application No. PCT/CN2021/120262, filed on Sep. 24, 2021.

(30) Foreign Application Priority Data
Jan. 8, 2021 (CN) 202110024313.0

(51) Int. Cl. H10B 12/00

(52) U.S. Cl. CPC H10B 12/482; H10B 12/485; H10B 12/37; H10B 12/0387

(57) ABSTRACT

Semiconductor structure and manufacturing method thereof are provided. The method includes providing a substrate provided with trenches spaced apart from each other and bit line structures spaced apart from each other, the bit line structures being at least partially located in the trenches; forming a first protection layer at least including a first side wall layer covering a side wall of each of the bit line structures and a second side wall layer covering a surface of each of the trenches; forming a second protection layer fully filling each of the trenches together with the first protection layer and at least including a silicon oxide layer formed by a thermal oxidation method; and forming a third protection layer at least covering a top surface, away from the substrate, of the second protection layer, the second and third protection layers covering a surface of the first side wall layer.

### CROSS-REFERENCE TO RELATED APPLICATIONS

This is a continuation of International Patent Application No. PCT/CN2021/120262, filed on Sep. 24, 2021, which claims priority to Chinese Patent Application No. 202110024313.0, filed on Jan. 8, 2021. The disclosures of International Patent Application No. PCT/CN2021/120262 and Chinese Patent Application No. 202110024313.0 are hereby incorporated by reference in their entireties.

### BACKGROUND

As a semiconductor process is miniaturized, the physical size of a bit line structure is miniaturized, and the physical size of an insulating layer around the bit line structure to protect it is miniaturized. However, when other conductive structures are formed in a semiconductor structure, the insulating layer for protecting the bit line structure is easily damaged, which exposes part of the bit line structure, and then electrical connections are formed between other conductive structure and the bit line structure, resulting in a short circuit; part of the bit line structure will even be damaged, which results in the loss of the bit line structure, thus reducing the yield of the semiconductor structure.

### SUMMARY

Embodiments of the present disclosure relate to the field of semiconductors, and in particular to a semiconductor structure and a manufacturing method thereof.

According to a first aspect of the present disclosure, there is provided a method for manufacturing a semiconductor structure, which includes the following operations. A substrate provided with a plurality of trenches spaced apart from each other and a plurality of bit line structures spaced apart from each other is provided, the bit line structures being at least partially located in the trenches. A first protection layer at least including a first side wall layer covering a side wall of each of the bit line structures and a second side wall layer covering a surface of each of the trenches is formed. A second protection layer fully filling each of the trenches together with the first protection layer and at least including a silicon oxide layer formed by a thermal oxidation method is formed. A third protection layer at least covering a top surface, away from the substrate, of the second protection layer is formed, the second protection layer and the third protection layer covering a surface of the first side wall layer.

According to a second aspect of the present disclosure, there is provided a semiconductor structure, which includes: a substrate, a first protection layer, a second protection layer, and a third protection layer. The substrate is provided with a plurality of trenches spaced apart from each other and a plurality of bit line structures spaced apart from each other, and the bit line structures are at least partially located in the trenches. The first protection layer at least includes a first side wall layer covering a side wall of each of the bit line structures and a second side wall layer covering a surface of each of the trenches. The second protection layer fully fills each of the trenches together with the first protection layer, and at least includes a silicon oxide layer formed by a thermal oxidation method. The third protection layer at least covers a top surface, away from the substrate, of the second protection layer, and the second protection layer and the third protection layer cover a surface of the first side wall layer.

### BRIEF DESCRIPTION OF THE DRAWINGS

One or more embodiments are illustrated through the figures in the accompanying drawings corresponding to the one or more embodiments, and the figures do not constitute a scale limit unless otherwise stated.

FIG. 1 to FIG. 5 are schematic diagrams of section structures corresponding to the steps in a method for manufacturing a semiconductor structure provided in the first embodiment of the present disclosure.

FIG. 6 to FIG. 15 are schematic diagrams of section structures corresponding to the steps in a method for manufacturing a semiconductor structure provided in the second embodiment of the present disclosure.

### DETAILED DESCRIPTION

From the background technology, an insulating layer for protecting a bit line structure in the conventional art is easy to be damaged, which reduces the protection effect of the insulating layer on the bit line structure.

A analysis shows that the physical size of the insulating layer for protecting the bit line structure is small, it is not easy to control an etch stop point when part of the insulating layer and part of a substrate for carrying the bit line structure are etched subsequently to form a capacitor contact hole, so it is easy to etch part of the insulating layer located on the side wall of the bit line structure, thereby exposing part of the bit line structure, and when the capacitor contact hole is filled with conductive material to form a capacitor contact plug, the capacitor contact plug is connected to a bit line contact layer, resulting in a short circuit between the bit line structure and the capacitor contact plug. In addition, the subsequent etching process will even cause damage to the bit line structure, so that part of the bit line structure is lost, affecting the normal operation of the semiconductor structure.

An embodiment of the present disclosure provides a method for manufacturing a semiconductor structure. A first protection layer and a second protection layer fully fill a trench, the first protection layer at least includes a first side wall layer covering the side wall of the bit line structure and a second side wall layer covering the surface of the trench, and the second protection layer at least includes a silicon oxide layer formed by a thermal oxidation method; in addition, a third protection layer is formed on the top surface, away from the substrate, of the second protection layer, and the second protection layer and the third protection layer cover the surface of the first side wall layer. Therefore, the first protection layer, the second protection layer and the third protection layer jointly constitute the insulating layer for protecting the bit line structure, which helps to protect the bit line structure well when part of the insulating layer fully fills the trench, so that the yield of the semiconductor structure can meet the requirement.

In order to make the purpose, technical solutions and advantages of the embodiments of the present disclosure clearer, the embodiments of the present disclosure will be described in detail below in combination with the accompanying drawings. However, those of ordinary skill in the art may understand that many technical details are presented in the embodiments of the present disclosure to make the present disclosure better understood by the reader. However, the technical solution claimed by the present disclosure may also be implemented even without these technical details, and changes and modifications based on the following embodiments.

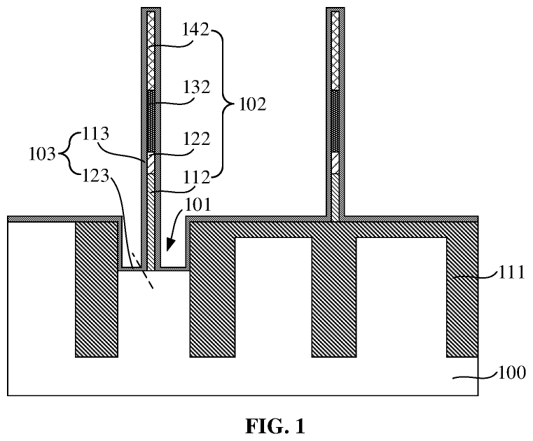

FIG. 1 to FIG. 5 are schematic diagrams of section structures corresponding to the steps in a method for manufacturing a semiconductor structure provided in the first embodiment of the present disclosure.

Referring to FIG. 1, the method for manufacturing a semiconductor structure may include that: a substrate 100 is provided. The substrate 100 is provided with a plurality of trenches 101 spaced apart from each other and a plurality of bit line structures 102 spaced apart from each other, and the bit line structures 102 are at least partially located in the trenches 101.

Specifically, the bit line structure 102 includes a bit line contact layer 112, a diffusion barrier layer 122, a bit line conductive layer 132 and a bit line insulating layer 142 stacked successively. The material of the bit line contact layer 112 is polycrystalline silicon, the material of the diffusion barrier layer 122 is titanium nitride, the material of the bit line conductive layer 132 is tungsten, and the material of the bit line insulating layer 142 is silicon nitride.

In the present embodiment, the substrate 100 is also provided with a plurality of shallow trench isolation structures 111 spaced apart from each other; each of the bit line structures 102 includes a first bit line structure and a second bit line structure; the first bit line structure is partially located in the trench 101; and the second bit line structure is located on the shallow trench isolation structure 111.

Referring to FIG. 1, a first protection layer 103 is formed. The first protection layer 103 at least includes a first side wall layer 113 covering a side wall of each of the bit line structures 102 and a second side wall layer 123 covering a surface of each of the trenches 101.

Specifically, the first side wall layer 113 is located on two side walls of the bit line structure 102, and the second side wall layer 123 is located at the bottom and the side wall of the trench 101. The dotted line in FIG. 1 is the dividing line between the first side wall layer 113 and the second side wall layer 123.

In the present embodiment, the methods for forming the first protection layer 103 include a chemical vapor deposition method or an atomic layer deposition method, etc., so the first protection layer 103 also covers the surface of the substrate 100 and the top of the bit line structure 102, and when high-temperature oxidation is performed on the semiconductor structure later, it is beneficial to protect the bit line structure 102 and the substrate 100 through the first protection layer 103 and avoid the oxidation reaction between the bit line structure 102 and the substrate 100, thereby preventing the material characteristics of the bit line structure 102 and the substrate 100 from changing to affect the working performance of the semiconductor structure. In addition, the material of the first protection layer 103 may be silicon nitride.

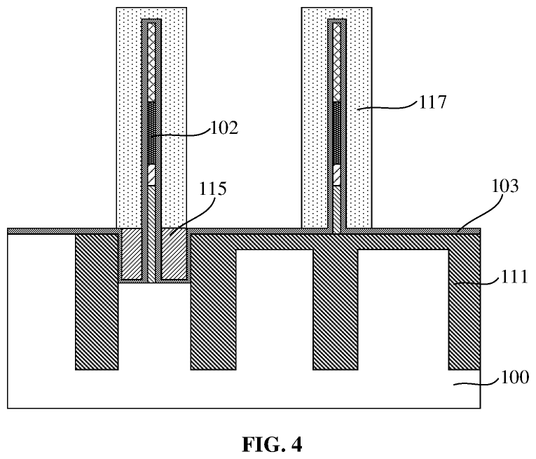

Referring to FIG. 4, a second protection layer 115 is formed. The first protection layer 103 and the second protection layer 115 fully fill each of the trenches, and the second protection layer 115 is a single-layer structure. Specifically, the second protection layer 115 is a silicon oxide layer formed by the thermal oxidation method.

Specifically, the processing step of forming the second protection layer may include the following operations.

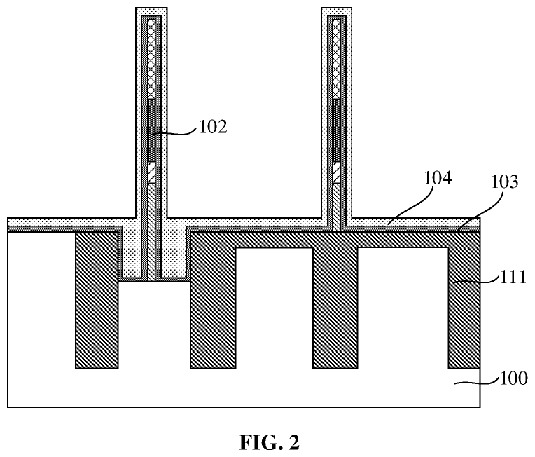

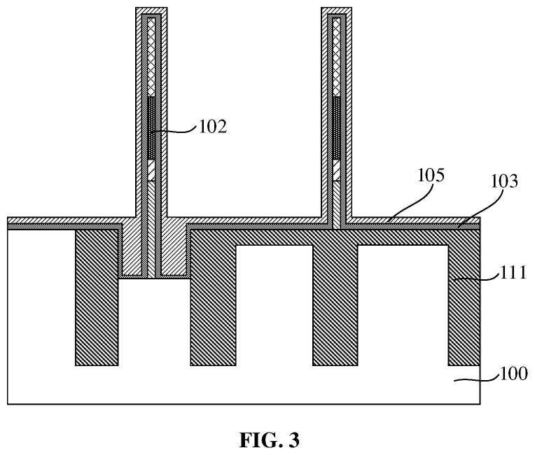

Referring to FIG. 2, a silicon material layer 104 is formed on a surface of the first protection layer 103. Referring to FIG. 3, thermal oxidation is performed on the silicon material layer 104 to form an initial silicon oxide layer 105. Referring to FIG. 4, part of the initial silicon oxide layer 105 is removed to form a silicon oxide layer.

In the present embodiment, the silicon oxide layer formed by the thermal oxidation method is beneficial to improve the density of the second protection layer 115. Since the first protection layer 103 and the second protection layer 115 fully fill the trench, so when part of the first protection layer 103 and part of the substrate 100 between the adjacent bit line structures 102 are removed by a first etching process to form a capacitor contact hole, the silicon oxide layer in the trench 101 can effectively resist the lateral etching of the first etching process, which is beneficial to reduce the etching rate of the first etching process on the second protection layer 115, thereby preventing the second protection layer 115 from being etched through in the subsequent step of forming the capacitor contact hole to expose the bit line contact layer 112 (referring to FIG. 1) of the bit line structure 102. Therefore, it is beneficial to improve the protection effect of the second protection layer 115 on the bit line structure 102.

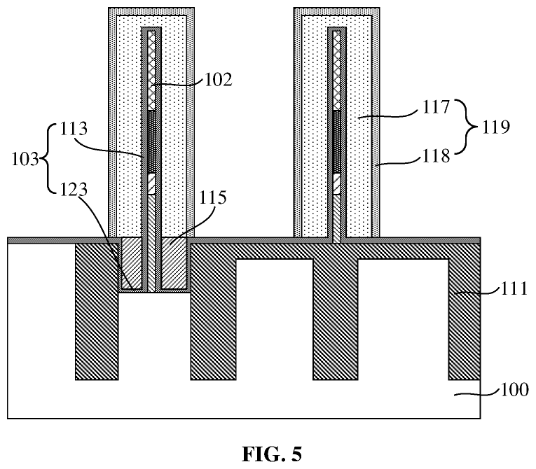

Referring to FIG. 4 and FIG. 5, a third protection layer 119 is formed. The third protection layer 119 at least covers a top surface, away from the substrate 100, of the second protection layer 115, and the second protection layer 115 and the third protection layer 119 cover a surface of the first side wall layer 113 (referring to FIG. 1). Specifically, the third protection layer 119 includes a second dielectric layer 117 and a third dielectric layer 118 stacked successively.

In the present embodiment, the third protection layer 119 and the first protection layer 103 jointly protect the bit line structure 102 higher than the opening of the trench 101, and the third protection layer 119 covers not only the top surface, away from the substrate 100, of the second protection layer 115, but also part of the first protection layer 103 located on the surface of the substrate 100. In this way, the bit line structure 102 can be well protected when the second protection layer 115 fully fills the trench 101.

The second embodiment of the present disclosure also provides a method for manufacturing a semiconductor structure. This embodiment is roughly the same as the foregoing embodiment, and the main difference lies in the different processing steps of forming the second protection layer. The method for manufacturing a semiconductor structure provided in the second embodiment of the present disclosure will be described in detail in combination with the accompanying drawings. It is to be noted that the part same as or corresponding to the above embodiment may refer to the detailed description of the above embodiment, and elaborations are omitted herein.

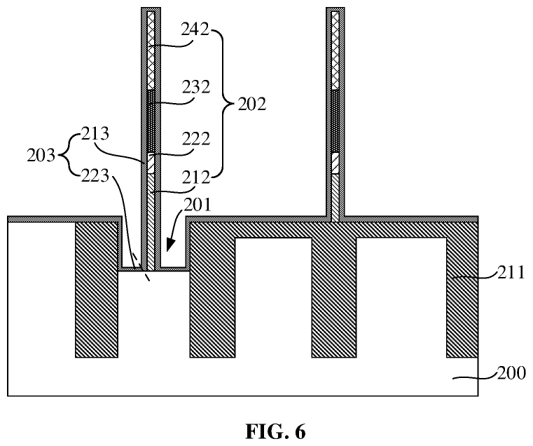

Referring to FIG. 6, the method for manufacturing a semiconductor structure may include that: a substrate 200 is provided. The substrate 200 is provided with a plurality of trenches 201 spaced apart from each other and a plurality of bit line structures 202 spaced apart from each other, and the bit line structures 202 are at least partially located in the trenches 201. Specifically, the bit line structure 202 includes a bit line contact layer 212, a diffusion barrier layer 222, a bit line conductive layer 232 and a bit line insulating layer 242 stacked successively. In the embodiment, the substrate 200 is also provided with a plurality of shallow trench isolation structures 211 spaced apart from each other.

Referring to FIG. 6, a first protection layer 203 is formed. The first protection layer 203 at least includes a first side wall layer 213 covering a side wall of each of the bit line structures 202 and a second side wall layer 223 covering a surface of each of the trenches 201, and the first protection layer 203 also covers the surface of the substrate 200 and the top of the bit line structure 202.

Specifically, the first side wall layer 213 is located on two side walls of the bit line structure 202, and the second side wall layer 223 is located at the bottom and the side wall of the trench 201. The dotted line in FIG. 6 is the dividing line between the first side wall layer 213 and the second side wall layer 223.

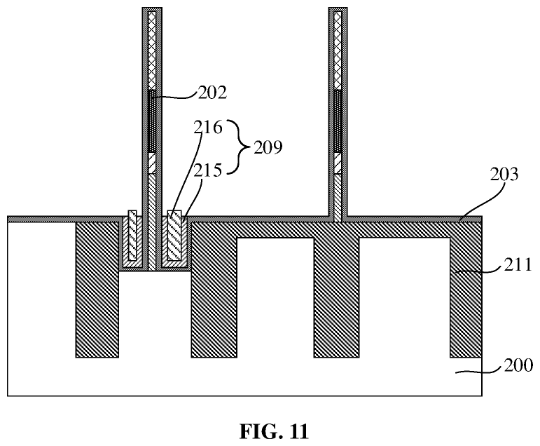

Referring to FIG. 11, a second protection layer 209 is formed, and the first protection layer 203 and the second protection layer 209 fully fill each of the trenches. In the present embodiment, the second protection layer 209 is a double-layer structure. Specifically, the processing step of forming the second protection layer 209 may include the following operation.

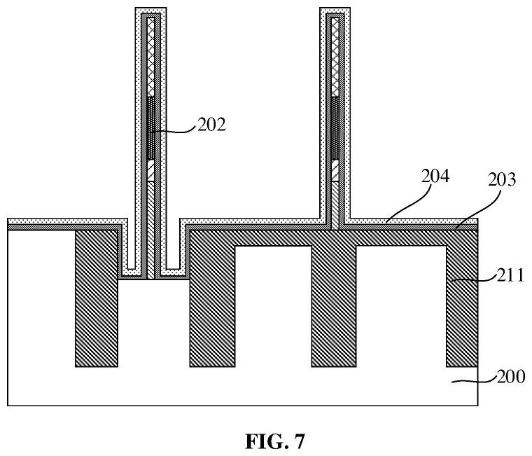

Referring to FIG. 7, a silicon material layer 204 is formed on a surface of the first protection layer 203. In the present embodiment, because the first protection layer 203 covers the substrate 100, the trench 201 and the surface of the bit line structure 202, the silicon material layer 204 is also located on the substrate 200, in the trench 201 and on the surface of the bit line structure 202. Accordingly, the method for forming the silicon material layer 204 may be the same as the method for forming the first protection layer 203, specifically either the chemical vapor deposition method or the epitaxial deposition method. In other embodiments, the method for forming the silicon material layer may also be different from the method for forming the first protection layer. In addition, the silicon material layer 204 may be monocrystalline silicon, polycrystalline silicon, or amorphous silicon.

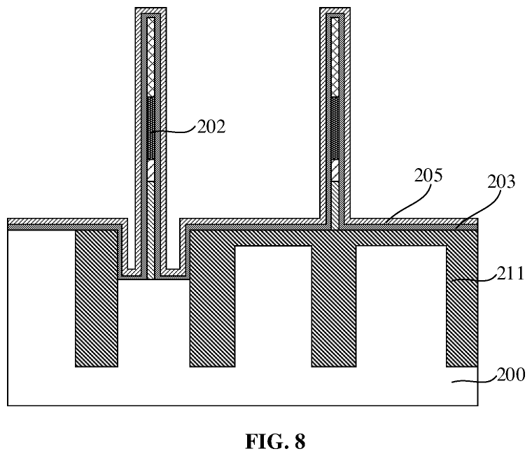

Referring to FIG. 8, thermal oxidation is performed on the silicon material layer 204 (referring to FIG. 7) to form an initial silicon oxide layer 205. In the present embodiment, the density of the initial silicon oxide layer 205 is greater than that of the silicon material layer 204, which is beneficial to improve the protection effect of the second protection layer formed subsequently on the bit line structure 202.

Specifically, the thermal oxidation is performed at a temperature of 1000° C. to 1500° C. Preferably, the thermal oxidation is performed at a temperature of 1250° C., which is beneficial to avoid excessively high temperature in a chamber while ensuring that the density of the initial silicon oxide layer 205 formed by the thermal oxidation meets the requirements. The excessively high temperature will cause severe thermal expansion of other structures in the semiconductor structure, resulting in poor contact between related structures and then affecting the overall stability of the semiconductor structure.

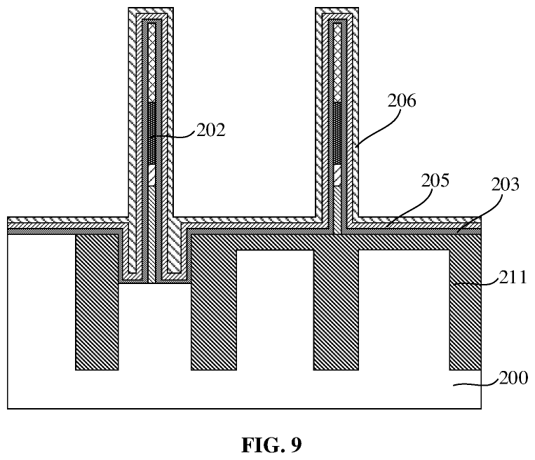

Referring to FIG. 9, an initial first dielectric layer 206 is formed on the surface of the initial silicon oxide layer 205 (referring to FIG. 8), and the initial first dielectric layer 206 is also located on the substrate 200, in the trench 201, and on the surface of the bit line structure 202. Further, part of the initial first dielectric layer 206 and part of the initial silicon oxide layer 205 jointly constitute the subsequent second protection layer, and part of the first protection layer 203 and the second protection layer formed subsequently jointly fill the trench 201 fully.

In the present embodiment, the method for forming the initial first dielectric layer 206 may be the same as the method for forming the first protection layer 203, and may be either the chemical vapor deposition method or the atomic layer deposition method. In other embodiments, the method for forming the initial first dielectric layer may also be different from the method for forming the first protection layer. In addition, the initial first dielectric layer 206 may be a silicon nitride layer.

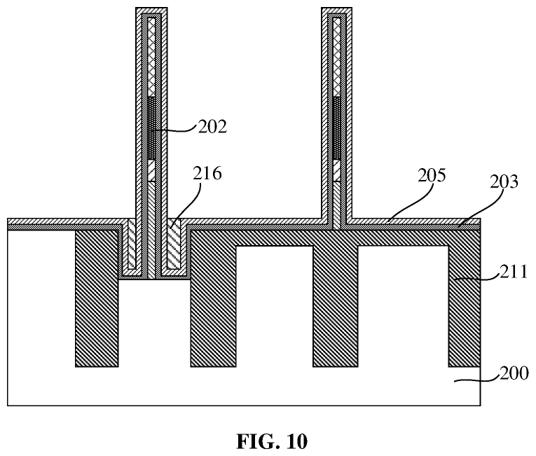

Referring to FIG. 10, part of the initial first dielectric layer 206 (referring to FIG. 9) is removed to form a first dielectric layer 216.

Specifically, the processing step of removing part of the initial first dielectric layer 206 to form the first dielectric layer 216 may include that: part of the initial first dielectric layer 206 is etched by a first plasma etching process to form the first dielectric layer 216, by taking the initial oxide layer 205 as a first etch stop layer.

In the present embodiment, the density difference between the initial first dielectric layer 206 and the initial oxide layer 205 is large, so when the initial first dielectric layer 206 is etched by the first plasma etching process to expose the initial oxide layer 205, the etching rate of the first plasma etching process changes significantly, which is beneficial to avoid the damage of the first plasma etching process to the initial first dielectric layer 206 in the trench 201 by taking the initial oxide layer 205 as the first etch stop layer. From the perspective of manufacturing process, reducing the etching error of the first plasma etching process makes the physical size of the second protection layer formed subsequently more accurate, which is beneficial to further strengthen the protection effect of the second protection layer formed subsequently on the bit line structure 202.

Specifically, under the same first plasma etching process conditions, the etch selectivity ratio of the initial first dielectric layer 206 to the initial oxide layer 205 is greater than 10:1, which is beneficial to accurately stop etching the initial first dielectric layer 206 by the first plasma etching process when the initial oxide layer 205 is exposed.

In the present embodiment, when the initial first dielectric layer 206 is etched by the first plasma etching process to form the first dielectric layer 216, the first plasma etching process stops at the top surface, away from the substrate 200, of the initial silicon oxide layer 205, so the top surface, away from the substrate 200, of the first dielectric layer 216 is flush with the top surface, away from the substrate 200, of the initial silicon oxide layer 205.

Referring to FIG. 11, part of the initial silicon oxide layer 205 (referring to FIG. 10) is removed to form a silicon oxide layer 215. The first dielectric layer 216 and the silicon oxide layer 215 constitute the second protection layer 209.

Specifically, the processing step of removing part of the initial silicon oxide layer 205 to form the silicon oxide layer 215 may include that: part of the initial silicon oxide layer 205 is etched by a second plasma etching process to form the silicon oxide layer 215, by taking the first protection layer 203 as a second etch stop layer. The first dielectric layer 216 and the silicon oxide layer 215 jointly constitute the second protection layer 209.

In the present embodiment, the density difference between the initial silicon oxide layer 205 and the first protection layer 203 is large, so when the initial silicon oxide layer 205 is etched by the second plasma etching process to expose the first protection layer 103, the etching rate of the second plasma etching process changes significantly, which is beneficial to avoid the damage of the second plasma etching process to the initial oxide layer 205 in the trench 201 by taking the first protection layer 203 as the second etch stop layer. From the perspective of manufacturing process, reducing the etching error of the second plasma etching process makes the physical size of the second protection layer formed subsequently more accurate, which is beneficial to further strengthen the protection effect of the second protection layer formed subsequently on the bit line structure 202.

Specifically, under the same plasma etching process conditions, the etch selectivity ratio of the initial silicon oxide layer 205 to the first protection layer 203 is greater than 10:1, which is beneficial to accurately stop etching the initial silicon oxide layer 205 by the second plasma etching process when the first protection layer 203 is exposed.

In the present embodiment, when the initial silicon oxide layer 205 is etched by the second plasma etching process to form the silicon oxide layer 215, the second plasma etching process stops at the top surface, away from the substrate 200, of the first protection layer 203, so the top surface, away from the substrate 200, of the silicon oxide layer 215 is flush with the top surface, away from the substrate 200, of the first protection layer 203, and then the top surface, away from the substrate 200, of the first dielectric layer 216 is slightly higher than the top surface, away from the substrate 200, of the silicon oxide layer 215. Further, the material of the first dielectric layer 216 is silicon nitride, and the density of the first dielectric layer 216 is greater than that of the silicon oxide layer 215, which is beneficial to further increase the overall density of the second protection layer 209 and thus to further strengthen the protection effect of the second protection layer 209 on the bit line structure 202.

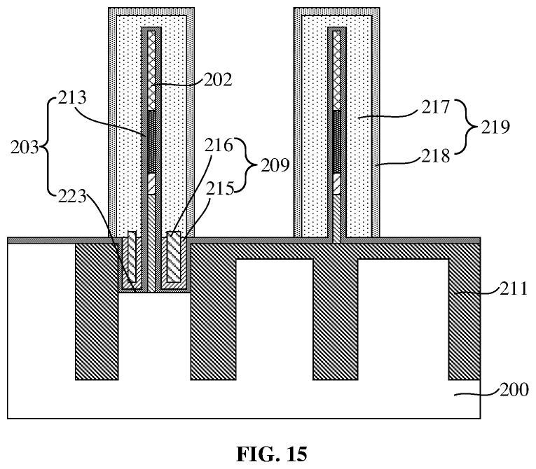

Referring to FIG. 15, a third protection layer 29 is formed. The third protection layer 219 at least covers the top surface, away from the substrate 200, of the second protection layer 209, and the second protection layer 209 and the third protection layer 219 cover the surface of the first side wall layer 213 (referring to FIG. 6).

In the present embodiment, the third protection layer 219 and the first protection layer 203 jointly protect the bit line structure 202 higher than the opening of the trench 201, and the third protection layer 219 covers not only the top surface, away from the substrate 200, of the second protection layer 209, but also a part of the first protection layer 203 located on the surface of the substrate 200.

Specifically, the processing step of forming the third protection layer 219 may include the following operation.

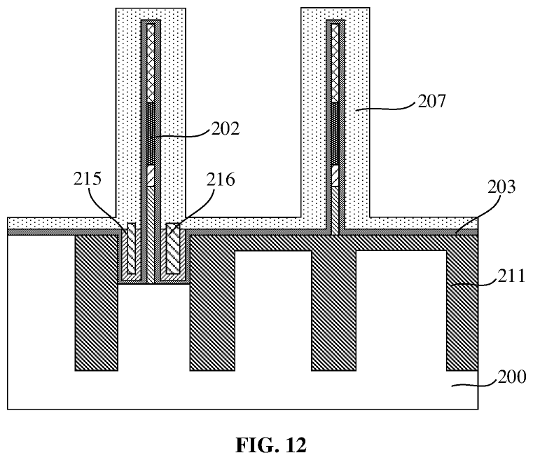

Referring to FIG. 12, an initial second dielectric layer 207 is deposited on the top surface, away from the substrate 200, of the second protection layer 209 (referring to FIG. 11) and part of the surface of the first protection layer 203. Here, part of the surface of the first protection layer 203 refers to the surface exposed to air of the first protection layer 203.

In the present embodiment, the thickness of the initial second dielectric layer 207 is greater than the thickness of the second protection layer 209 in a direction perpendicular to the extension direction of the bit line structure 202, that is, the initial second dielectric layer 207 covers not only the top surface, away from the substrate 200, of the silicon oxide layer 215, but also the top surface, away from the substrate 200, of the first dielectric layer 216. In addition, the methods for forming the initial second dielectric layer 207 include the chemical vapor deposition method or the atomic layer deposition method, and the material of the initial second dielectric layer 207 may be silicon oxide

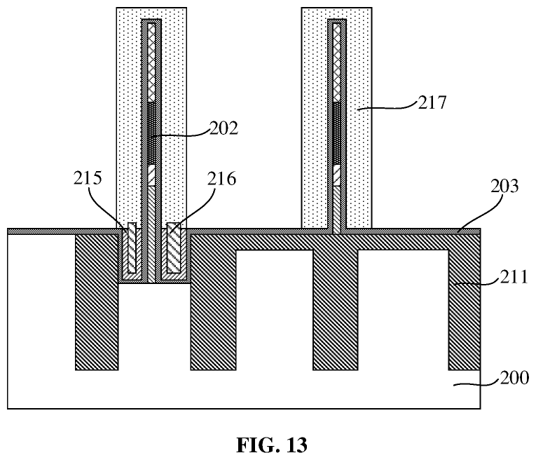

Referring to FIG. 13, part of the initial second dielectric layer 207 is removed to form a second dielectric layer 217. In the present embodiment, the second dielectric layer 217 is located on the top of the bit line structure 202, and also covers the top surface, away from the substrate 200, of the second protection layer 209 and part of the first side wall layer 213 (referring to FIG. 1). Because the thickness of the second dielectric layer 217 is higher in the direction perpendicular to the extension direction of the bit line structure 202, when a capacitor contact hole is formed between the adjacent bit line structures 202 by the etching process, it is beneficial to improve the insulativity between the second dielectric layer 217 and the capacitor contact plug and prevent the etching process from etching through the second dielectric layer 217 to expose the bit line structure 202. Moreover, the dielectric constant of the second dielectric layer 217 is smaller than that of the first protection layer 203, so when the capacitor contact plug is formed between the adjacent bit line structures 202 and a capacitor is formed on the capacitor contact plug subsequently, the second dielectric layer 217 is beneficial to reduce the parasitic capacitance between the bit line structure 202 and the capacitor contact plug as well as the capacitor, so as to reduce the probability of signal delay in the semiconductor structure, thereby helping to improve the electrical performance of the semiconductor structure.

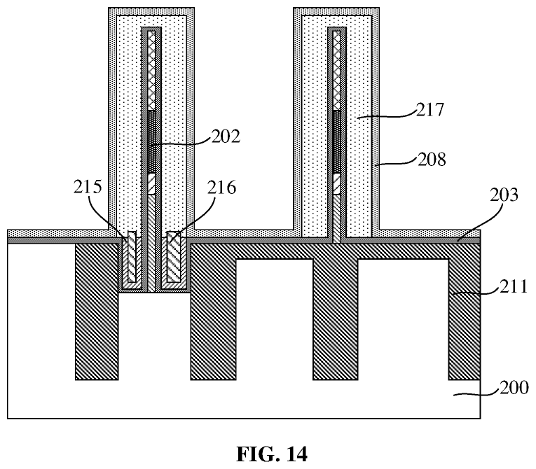

Referring to FIG. 14, an initial third dielectric layer 208 is deposited on the surface of the second dielectric layer 217. The methods for forming the initial third dielectric layer 208 include the chemical vapor deposition method or the atomic layer deposition method, and the material of the initial third dielectric layer 208 may be silicon nitride.

Referring to FIG. 15, part of the initial third dielectric layer 208 (referring to FIG. 14) is removed to form a third dielectric layer 218. The second dielectric layer 217 and the third dielectric layer 218 constitute a third protection layer 219.

In other embodiments, the initial third dielectric layer may also be formed directly on the surface of the initial second dielectric layer after the initial second dielectric layer is formed, and then part of the initial third dielectric layer and part of the initial second dielectric layer are removed to form the third dielectric layer and the second dielectric layer.

Specifically, the dielectric constant of the second dielectric layer 217 is less than that of the third dielectric layer 218, and the density of the material of the second dielectric layer 217 is less than that of the third dielectric layer 218. Therefore, the whole third protection layer 219 composed of the second dielectric layer 217 and the third dielectric layer 218 has not only a more appropriate dielectric constant but also a more appropriate density. In this way, when the capacitor contact plug is formed between the adjacent bit line structures 202 and the capacitor is formed on the capacitor contact plug subsequently, the third protection layer 219 is beneficial to not only reduce the parasitic capacitance between the bit line structure 202 and the capacitor contact plug as well as the capacitor, but also resist the lateral etching of the subsequent etching process, so as to prevent the bit line structure 202 from being etched.

In the present embodiment, the material of the third dielectric layer 218 is the same as the first protection layer 203, so when the third dielectric layer 218 and the first protection layer 203 located on the surface of the substrate 200 may be removed by the same etching process, it is beneficial to simplify the steps of the process of manufacturing the semiconductor structure.

To sum up, in the present embodiment, the second protection layer 209 is formed in the trench 201, and the second protection layer 209 at least includes the silicon oxide layer 215 formed by the thermal oxidation method, so that when other conductive structures are subsequently formed in the semiconductor structure by the etching process, both the first protection layer 203 located on the surface of the trench 201 and the silicon oxide layer 215 formed by thermal oxidation can resist the lateral etching of the etching process. In this way, at least one of the first protection layer 203 and the silicon oxide layer 215 is less etched at the end of the etching process, thus helping to improve the protection effect of the first protection layer 203 and the silicon oxide layer 215 on the bit line structure 202. Moreover, the third protection layer 219 and the second protection layer 209 jointly cover the surface of the first side wall layer 213 of the first protection layer 203, which is beneficial to further strengthen the protection effect on the bit line structure 202. In addition, setting the third protection layer 219 through the materials with different dielectric constants is beneficial to reducing the parasitic capacitance between the bit line structure 202 and other conductive structures formed subsequently, thereby reducing the delay effect between the bit line structure 202 and other conductive structures and helping to improve the electrical performance of the semiconductor structure.

Correspondingly, the third embodiment of the present disclosure also provides a semiconductor structure, which is manufactured by the method for manufacturing a semiconductor structure provided in the first embodiment above.

Referring to FIG. 5, the semiconductor structure may include: a substrate 100, a first protection layer 103, a second protection layer 115, and a third protection layer 119. The substrate 100 is provided with a plurality of trenches 101 (referring to FIG. 1) spaced apart from each other and a plurality of bit line structures 102 spaced apart from each other, and the bit line structures 102 are at least partially located in the trenches 101. The first protection layer 103 at least includes a first side wall layer 113 covering a side wall of each of the bit line structures 102 and a second side wall layer 123 covering a surface of each of the trenches 101. The first protection layer 103 and the second protection layer 115 fully fill each of the trenches 101, and the second protection layer 115 at least includes a silicon oxide layer formed by the thermal oxidation method. The third protection layer 119 at least covers a top surface, away from the substrate 100, of the second protection layer 115, and the second protection layer 115 and the third protection layer 119 cover a surface of the first side wall layer 113.

In the present embodiment, the first protection layer 103 is also located on a top of the bit line structure 102, and the second protection layer 115 is a single-layer structure. Specifically, the second protection layer 115 is a silicon oxide layer with a high density formed by the thermal oxidation method, and the first protection layer 103, the second protection layer 115 and the third protection layer 119 jointly wrap the bit line structure 102. In this way, when other conductive structures are formed in the semiconductor structure by the etching process, it is beneficial to resisting the lateral etching of the etching process, so as to avoid exposing the bit line structure 102 and causing the loss of the bit line structure 102.

The third protection layer 119 includes a second dielectric layer 117 and a third dielectric layer 118. The second dielectric layer 117 and the second protection layer 115 cover the surface of the first side wall layer 113 as well as a part of the first protection layer 103 located on the surface of the substrate 100. The third dielectric layer 118 covers a surface of the second dielectric layer 117. Moreover, a dielectric constant of the second dielectric layer 117 is smaller than that of the third dielectric layer 118. Further, the material of the second dielectric layer 117 may be silicon oxide, and the material of the third dielectric layer 118 may be silicon nitride, which is beneficial to reduce the parasitic capacitance between the bit line structure 102 and other conductive structures formed subsequently and thus help to improve the electrical performance of the semiconductor structure.

The fourth embodiment of the present disclosure also provides a semiconductor structure. This embodiment is roughly the same as the foregoing embodiment, and the main difference lies in that the second protection layer is a single-layer structure. The semiconductor structure provided in the fourth embodiment of the present disclosure will be described in detail in combination with the accompanying drawings. It is to be noted that the part same as or corresponding to the above embodiments may refer to the detailed description of the above embodiments, and elaborations are omitted herein.

Referring to FIG. 15, the semiconductor structure may include: a substrate 200, a first protection layer 203, a second protection layer 209, and a third protection layer 229. The substrate 200 is provided with a plurality of trenches 201 (referring to FIG. 6) spaced apart from each other and a plurality of bit line structures 202 spaced apart from each other, and the bit line structures 202 are at least partially located in the trenches 201. The first protection layer 203 at least includes a first side wall layer 213 covering a side wall of each of the bit line structures 202 and a second side wall layer 223 covering a surface of each of the trenches 101. The first protection layer 203 and the second protection layer 209 fully fill each of the trenches 201, and the second protection layer 209 at least includes a silicon oxide layer 215 formed by the thermal oxidation method. The third protection layer 229 at least covers a top surface, away from the substrate 200, of the second protection layer 209, and the second protection layer 209 and the third protection layer 229 cover a surface of the first side wall layer 213.

Specifically, the second protection layer 209 includes a silicon oxide layer 215 and a first dielectric layer 216. The silicon oxide layer 215 covers a surface of the second side wall layer 223 and part of the surface of the first side wall layer 213. The first dielectric layer 216 covers a surface of the silicon oxide layer 215. A dielectric constant of the silicon oxide layer 215 is smaller than that of the first dielectric layer 216, which is beneficial to reduce the parasitic capacitance between the bit line structure 202 and other conductive structures formed subsequently. In addition, because the first dielectric layer 216 is conducive to improving the overall thickness of the second protection layer 209, when part of the first protection layer 203 and part of the substrate 200 between the adjacent bit line structures 202 are removed by the etching process to form a capacitor contact hole, the second protection layer 209 can effectively resist the lateral etching of the etching process, which is beneficial to reduce the etching rate of the etching process on the second protection layer 209, and preventing the second protection layer 209 from being etched through to expose the bit line contact layer 212 (referring to FIG. 6) of the bit line structure 202, in the subsequent step of forming the capacitor contact hole. Therefore, it is beneficial to improve the protection effect of the second protection layer 209 on the bit line structure 202.

The third protection layer 219 includes a second dielectric layer 217 and a third dielectric layer 218. The second dielectric layer 217 and the silicon oxide layer 215 cover the surface of the first side wall layer 213. The third dielectric layer 218 covers a surface of the second dielectric layer 217.

Those of ordinary skill in the art may understand that the above embodiments are the specific embodiments for implementing the present disclosure. In practical applications, various modifications may be made for them in form and detail without departing from the spirit and scope of the present disclosure. Those skilled in the art may make their own changes and modifications without departing from the spirit and scope of the present disclosure. Therefore, the scope of protection of the present disclosure shall be subject to the scope limited by the claims.

What is claimed is:

1. A method for manufacturing a semiconductor structure, comprising:
providing a substrate provided with a plurality of trenches spaced apart from each other and a plurality of bit line structures spaced apart from each other, wherein the bit line structures are at least partially located in the trenches;
forming a first protection layer at least comprising a first side wall layer covering a side wall of each of the bit line structures and a second side wall layer covering a surface of each of the trenches;
forming a second protection layer fully filling each of the trenches together with the first protection layer and at least comprising a silicon oxide layer formed by a thermal oxidation method; and
forming a third protection layer at least covering a top surface, away from the substrate, of the second protection layer, wherein the second protection layer and the third protection layer cover a surface of the first side wall layer.

2. The method for manufacturing the semiconductor structure of claim 1, wherein the substrate is also provided with a plurality of shallow trench isolation structures spaced apart from each other; each of the bit line structures comprises a first bit line structure and a second bit line structure; the first bit line structure is partially located in the trench; and the second bit line structure is located on the shallow trench isolation structure.

3. The method for manufacturing the semiconductor structure of claim 1, wherein the processing step of forming the second protection layer fully filling each of the trenches together with the first protection layer and at least comprising the silicon oxide layer formed by the thermal oxidation method comprises:
forming a silicon material layer on a surface of the first protection layer;
performing thermal oxidation on the silicon material layer to form an initial silicon oxide layer;
forming an initial first dielectric layer on a surface of the initial silicon oxide layer;
removing part of the initial first dielectric layer to form a first dielectric layer; and
removing part of the initial silicon oxide layer to form the silicon oxide layer;
wherein the first dielectric layer and the silicon oxide layer constitute the second protection layer.

4. The method for manufacturing the semiconductor structure of claim 3, wherein the thermal oxidation is performed at a temperature of 1000° C. to 1500° C.

5. The method for manufacturing the semiconductor structure of claim 3, wherein the processing step of removing part of the initial first dielectric layer to form the first dielectric layer comprises:
etching part of the initial first dielectric layer by a first plasma etching process to form the first dielectric layer, by taking the initial oxide layer as a first etch stop layer.

6. The method for manufacturing the semiconductor structure of claim 5, wherein under same first plasma etching process conditions, an etch selectivity ratio of the initial first dielectric layer to the initial oxide layer is greater than 10:1.

7. The method for manufacturing the semiconductor structure of claim 3, wherein the processing step of removing part of the initial silicon oxide layer to form the silicon oxide layer comprises:
etching part of the initial silicon oxide layer by a second plasma etching process to form the silicon oxide layer, by taking the first protection layer as a second etch stop layer.

8. The method for manufacturing the semiconductor structure of claim 7, wherein under same second plasma etching process conditions, an etch selectivity ratio of the initial silicon oxide layer to the first protection layer is greater than 10:1.

9. The method for manufacturing the semiconductor structure of claim 1, wherein the processing step of forming the third protection layer comprises:
depositing an initial second dielectric layer on the top surface, away from the substrate, of the second protection layer and part of a surface of the first protection layer;
removing part of the initial second dielectric layer to form a second dielectric layer;
depositing an initial third dielectric layer on a surface of the second dielectric layer; and
removing part of the initial third dielectric layer to form a third dielectric layer;
wherein the second dielectric layer and the third dielectric layer constitute the third protection layer.

10. The method for manufacturing the semiconductor structure of claim 9, wherein a dielectric constant of the second dielectric layer is smaller than a dielectric constant of the first protection layer.

11. The method for manufacturing the semiconductor structure of claim 10, wherein the material of the third dielectric layer is the same as the material of the first protection layer.

12. The method for manufacturing the semiconductor structure of claim 11, wherein the density of the material of the second dielectric layer is less than the density of the material of the third dielectric layer.

13. The method for manufacturing the semiconductor structure of claim 2, wherein the processing step of forming the third protection layer comprises:
depositing an initial second dielectric layer on the top surface, away from the substrate, of the second protection layer and part of a surface of the first protection layer;
removing part of the initial second dielectric layer to form a second dielectric layer;
depositing an initial third dielectric layer on a surface of the second dielectric layer; and
removing part of the initial third dielectric layer to form a third dielectric layer;
wherein the second dielectric layer and the third dielectric layer constitute the third protection layer.

14. The method for manufacturing the semiconductor structure of claim 3, wherein the processing step of forming the third protection layer comprises:
depositing an initial second dielectric layer on the top surface, away from the substrate, of the second protection layer and part of a surface of the first protection layer;
removing part of the initial second dielectric layer to form a second dielectric layer;
depositing an initial third dielectric layer on a surface of the second dielectric layer; and
removing part of the initial third dielectric layer to form a third dielectric layer;
wherein the second dielectric layer and the third dielectric layer constitute the third protection layer.

15. A semiconductor structure, comprising:
a substrate, provided with a plurality of trenches spaced apart from each other and a plurality of bit line structures spaced apart from each other, wherein the bit line structures are at least partially located in the trenches;
a first protection layer, at least comprising a first side wall layer covering a side wall of each of the bit line structures and a second side wall layer covering a surface of each of the trenches;
a second protection layer fully filling each of the trenches together with the first protection layer, and at least comprising a silicon oxide layer formed by a thermal oxidation method; and
a third protection layer, at least covering a top surface, away from the substrate, of the second protection layer, wherein the second protection layer and the third protection layer cover a surface of the first side wall layer.

16. The semiconductor structure of claim 15, wherein the second protection layer comprises the silicon oxide layer and a first dielectric layer; the silicon oxide layer covers a surface of the second side wall layer and part of the surface of the first side wall layer; and the first dielectric layer covers a surface of the silicon oxide layer.

17. The semiconductor structure of claim 16, wherein the third protection layer comprises a second dielectric layer and a third dielectric layer; the second dielectric layer and the silicon oxide layer cover the surface of the first side wall layer; and the third dielectric layer covers a surface of the second dielectric layer.
